(19) United States
(12) Patent Application Publication
(10) Pub. No.: US 2020/0075321 A1
(43) Pub. Date: Mar. 5, 2020

(54) NON-UV HIGH HARDNESS LOW K FILM DEPOSITION

(71) Applicant: Applied Materials, Inc., Santa Clara, CA (US)

(72) Inventors: Shaunak MUKHERJEE, San Jose, CA (US); Bo XIE, San Jose, CA (US); Kevin Michael CHO, Fremont, CA (US); Kang Sub YIM, Palo Alto, CA (US); Deenesh PADHI, Sunnyvale, CA (US); Astha GARG, Sunnyvale, CA (US)

(21) Appl. No.: 16/552,294

(22) Filed: Aug. 27, 2019

Related U.S. Application Data
(60) Provisional application No. 62/724,317, filed on Aug. 29, 2018.

(51) Int. Cl. H01L 21/02; C23C 16/40; C23C 16/50

(52) U.S. Cl. CPC H01L 21/02126; H01L 21/02274; H01L 21/76807; C23C 16/401; C23C 16/50; H01L 21/02216

(57) ABSTRACT

Embodiments described herein provide a method of forming a low-k carbon-doped silicon oxide (CDO) layer having a high hardness by a plasma-enhanced chemical vapor deposition (PECVD) process. The method includes providing a carrier gas at a carrier gas flow rate and a CDO precursor at a precursor flow rate to a process chamber. A radio frequency (RF) power is applied at a power level and a frequency to the CDO precursor. The CDO layer is deposited on a substrate within the process chamber.

### CROSS-REFERENCE TO RELATED APPLICATIONS

This application claims priority to U.S. Provisional Patent Application Ser. No. 62/724,317, filed on Aug. 29, 2018, which herein is incorporated by reference.

### BACKGROUND

### Field

Embodiments of the present disclosure generally relate to manufacturing semiconductor devices. More particularly, embodiments of the present disclosure relate to manufacturing dual damascene structures with a low-k carbon-doped silicon oxide (CDO) layer having a high hardness by a plasma-enhanced chemical vapor deposition process.

### Description of the Related Art

In semiconductor manufacturing, various features may be formed. Such features include dual damascene structures having dielectric layers, such as low dielectric constant materials, also known a low-k layers, and conductive metal layers, such as conductive copper layers, stacked on top of dielectric layers. Vias and/or trenches may also be formed. The vias and/or trenches are etched into the low-k layers, and the conductive metal layers are subsequently filled into the vias and/or trenches and planarized, such as by a chemical mechanical planarization process (CMP), so that the conductive metal layers are planarized.

One example of a low-k layer utilized for dual damascene structures is a carbon-doped silicon oxide (CDO) layer deposited by a plasma-enhanced chemical vapor deposition (PECVD) process. The CDO layer is deposited by the PECVD process so that the CDO layer has a low dielectric constant, such as less than 3 k. However, conventional low-k CDO layers have a poor mechanical strength. Conventional low-k CDO is exposed to high shear stresses during the subsequent CMP process which can lead to cracks and device failure. The as deposited low-k CDO layer has a poor mechanical strength due to the inverse relationships of Young's modules and hardness to dielectric constant.

Therefore, there is a need in the art for a method of forming a low-k CDO layer having a high hardness by a PECVD process.

### SUMMARY

In one embodiment, a method of forming a carbon-doped silicon oxide (CDO) layer is provided. The method includes providing a carrier gas at a carrier gas flow rate and a CDO precursor at a precursor flow rate to a process chamber. The CDO precursor is selected from the group consisting of:

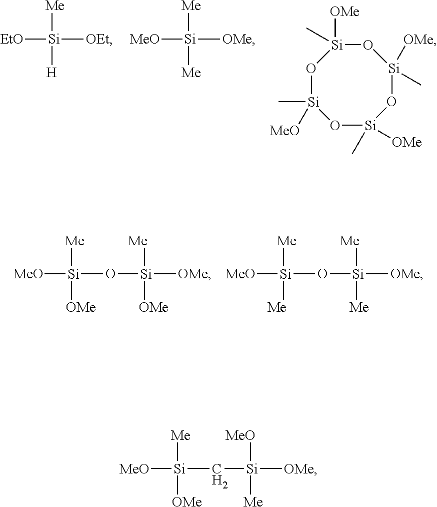

and mixtures thereof. A radio frequency (RF) power is applied at a power level and a frequency to the CDO precursor. The CDO layer is deposited on a substrate within the process chamber.

In another embodiment, a method of forming a CDO layer is provided. The method includes providing a carrier gas at a carrier gas flow rate and a CDO precursor at a precursor flow rate to a process chamber, the CDO precursor represented by Formula 1:

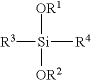

In Formula 1, R¹ and R₂ are independently selected from the group consisting of a C₁-C₂₀ alkyl group, R³ is selected from the group consisting of a C₁-C₂₀ alkyl group and hydrogen (H), and R⁴ is selected from the group consisting of a C₁-C₂₀ alkyl group and a C₁-C₂₀ alkoxy group. A RF power is applied at a power level and a frequency to the CDO precursor. The CDO layer is deposited on a substrate within the process chamber.

In yet another embodiment, a method of forming a CDO layer is provided. The method includes providing a carrier gas at a carrier gas flow rate and a CDO precursor at a precursor flow rate to a process chamber, the CDO precursor represented by Formula 1:

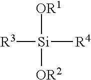

In Formula 1, R¹ is selected from the group consisting of —CH₃ and —CH₂CH₃, R² is selected from the group consisting of —CH₃ and —CH₂CH₃, R³ is selected from the group consisting of —CH₃ and H, and R⁴ is selected from the group consisting of

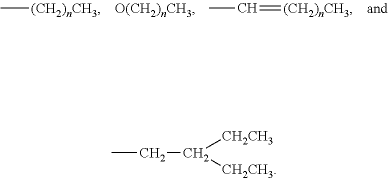

A RF power is applied at a power level and a frequency to the CDO precursor. The CDO layer is deposited on a substrate within the process chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic view of a system according to an embodiment.

FIG. 2 is a schematic cross-sectional view of a plasma-enhanced chemical vapor deposition system according to an embodiment.

FIG. 3 is a flow diagram of a method of forming a low-k silicon CDO layer by a plasma-enhanced chemical vapor deposition process according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide a method of forming a low-k carbon-doped silicon oxide (CDO) layer having a high hardness by a plasma-enhanced chemical vapor deposition (PECVD) process. The method includes providing a carrier gas at a carrier gas flow rate and a CDO precursor at a precursor flow rate to a process chamber. A radio frequency (RF) power is applied at a power level and a first frequency to the CDO precursor. The CDO layer is deposited on a substrate within the process chamber.

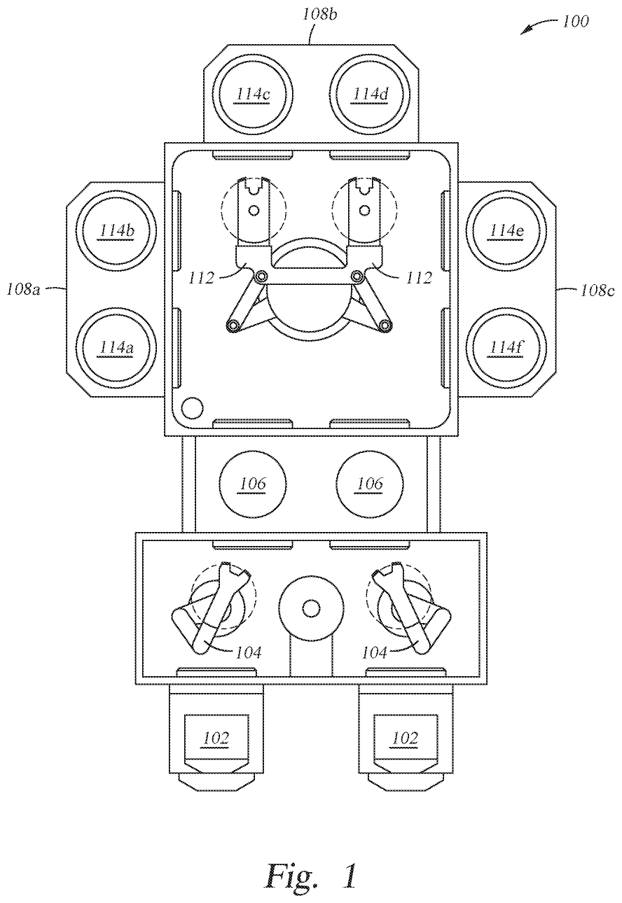

FIG. 1 is a schematic view of a system 100 utilized for a method of forming a low-k silicon CDO layer by a PECVD process. One example processing system 200 is a PRODUCER® platform, available from Applied Materials, Inc. of Santa Clara, Calif. It is to be understood that the system described below is an exemplary platform and other platforms, including platforms from other manufacturers, may be used with or modified to accomplish aspects of the present disclosure.

As shown in FIG. 1, a pair of front opening unified pods (FOUPs) 102 supplies substrates that are received by robotic arms 104 and placed into the holding area 106 before being placed into one of the process chambers 114a-114f of twin PECVD systems 108a-108c. A second robotic arm 112 may be used to transport the substrates from the holding area 106 to the PECVD systems 108a-108c. The PECVD systems 108a-108c are utilized to form a low-k CDO layer by a PECVD process.

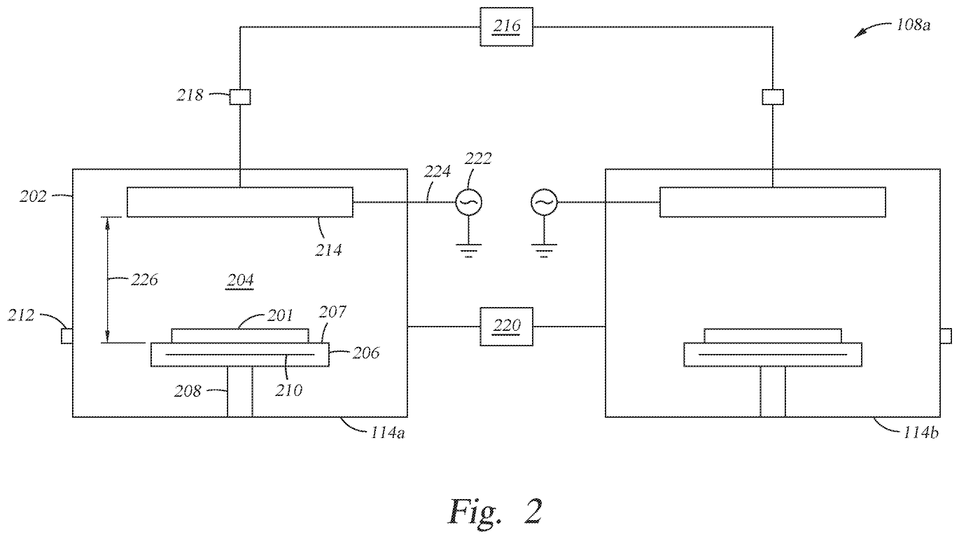

FIG. 2 is a schematic cross-sectional view of a PECVD system 108a utilized for a method of forming a low-k CDO layer by a PECVD process. One example of the system 100 is a PRECISION® system manufactured by Applied Materials, Inc., located in Santa Clara, Calif. It is to be understood that the system described below is an exemplary system and other systems, including systems from other manufacturers, may be used with or modified to accomplish aspects of the present disclosure.

As shown in FIG. 2, the system 108a includes the process chambers 114a, 114b, wherein the process chambers 114a, 114b share resources. For example, the process chambers 114a, 114b share resources such as a vacuum pump 220 and a gas source 216. The process chamber 114a (e.g., a first process chamber) and the process chamber 114b (e.g., a second process chamber) are similarly configured. The process chamber 114a has a chamber body 202 that includes a processing volume 204 that includes a substrate support 206 disposed therein to support a substrate 201. The substrate support 206 includes a heating element 210 and a mechanism (not shown) that retains the substrate 201 on a top surface 207 of the substrate support 206, such as an electrostatic chuck, a vacuum chuck, a substrate retaining clamp, or the like. The substrate support 206 is coupled to and movably disposed in the processing volume 204 by a stem 208 connected to a lift system (not shown) that moves the substrate support 206 between an elevated processing position and a lowered position that facilitates transfer of the substrate 201 to and from the system 108a through an opening 212.

The process chamber 114a includes a flow controller 218, such as a mass flow control (MFC) device, disposed between the gas source 216 and the chamber body 202 to control a flow rate of process gasses from the gas source 216 to a showerhead 214 used for distributing the process gasses across the processing volume 204. The showerhead 214 is connected to a RF power source 222 by a RF feed 224 for generating a plasma in the processing volume 204 from the process gasses. The RF power source 222 provides RF energy to the showerhead 214 to facilitate generation of a plasma between the showerhead 214 and the substrate support 206. The stem 208 is configured to move the substrate support 206 to an elevated processing position at a process distance 226 between top surface 207 and the showerhead 214. The vacuum pump 220 is coupled to the chamber body 202 for controlling the pressure within the processing volume 204. Process chamber 114a is similar to process chamber 114b.

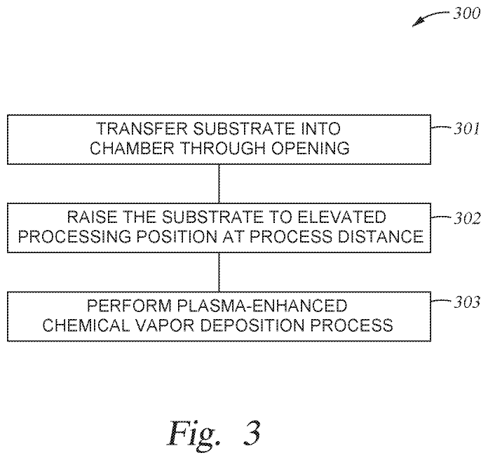

FIG. 3 is a flow diagram of a method 300 of forming a low-k CDO layer by a PECVD process. To facilitate explanation, FIG. 3 will be described with reference to FIG. 2. However, it is to be noted that a process chamber other than process chamber 114a of FIG. 2 may be utilized in conjunction with method 300.

At operation 301, a substrate 201 is transferred into the chamber through the opening 212. The substrate 201 is disposed on the top surface 207 of the substrate support 206 in the lowered position that facilitates transfer of the substrate 201 to and from the process chamber 114a through an opening 212. At operation 302, the substrate support 206 is raised to the elevated processing position at a process distance 226 between top surface 207 and the showerhead 214. The residence time of process gasses in the process chamber 114a may be controlled by the process distance 226. In one embodiment, which can be combined with other embodiments described herein, the process distance 226 is about 0.3 inches (in) to about 1.2 inches. Decreasing the process distance 226 increases plasma density to increase hardness and decrease the dielectric constant of the deposited CDO layer. Increasing the process distance 226 decreases plasma density to decrease hardness and increase the dielectric constant of the CDO layer.

At operation 303, a PECVD process is performed. The PECVD process forms a CDO layer on the substrate 101. In one embodiment, which can be combined with other embodiments described herein, during operation 203, a carrier gas at a carrier gas flow rate and a CDO precursor at a precursor flow rate are provided to the processing volume of the process chamber 114a. In another embodiment, which can be combined with other embodiments described herein, at least one of an oxygen-containing gas at an oxygen-containing gas flow rate and a hydrogen-containing gas at a hydrogen-containing gas flow rate are provided to into the processing volume 204 in addition to the carrier gas and CDO precursor. The flow controller 118 disposed between the gas source 116 and the chamber body 202 controls the carrier gas flow rate, the precursor flow rate, and at least one of the oxygen-containing gas flow rate and the hydrogen-containing gas flow rate. The showerhead 114 distributes the carrier gas, the CDO precursor gas, and the at least one of the oxygen-containing gas and the hydrogen-containing gas across the processing volume 204. In one embodiment, which can be combined with other embodiments described herein, the carrier gas includes helium (He) or Argon (Ar). In another embodiment, which can be combined with other embodiments described herein, the oxygen-containing gas includes oxygen gas (O₂) or carbon dioxide (CO₂). In yet another embodiment, which can be combined with other embodiments described herein, the hydrogen-containing gas includes hydrogen gas (H₂). The precursor flow rate is about 150 milligrams per minute (mgm) to about 2000 mgm, the carrier gas flow rate is about 100 standard cubic centimeters per minute (sccm) to about 5000 sccm, and at least one of the oxygen-containing gas flow rate is about 0 sccm to about 1000 sccm and the hydrogen-containing gas flow rate is about 0 sccm and 2000 sccm.

In some embodiments, which can be combined with other embodiments described herein, the CDO precursor includes at least one of the following compounds available from Applied Materials, Inc., located in Santa Clara, Calif.:

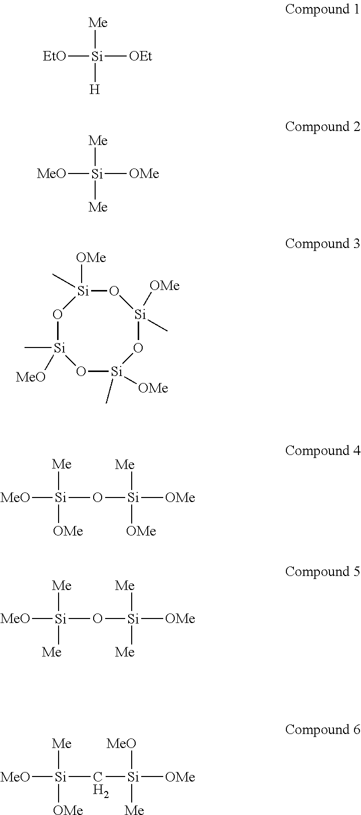

where Et is an ethyl group having the formula C₂H₅ and Me is a methyl group having the formula CH₃.

In other embodiments, which can be combined with other embodiments described herein, the CDO precursor, available from Applied Materials, Inc., is represented by Formula 1:

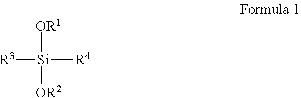

where, in Formula 1, R¹ and R² are independently selected from the group consisting of a C₁-C₂₀ alkyl group, R³ is selected from the group consisting of a C₁-C₂₀ alkyl group and hydrogen (H), and R⁴ is selected from the group consisting of a C₁-C₂₀ alkyl group and a C₁-C₂₀ alkoxy group. In one example of Formula 1, R¹ is selected from the group consisting of —CH₃ and —CH₂CH₃, R² is selected from the group consisting of —CH₃ and —CH₂CH₃, R³ is selected from the group consisting of —CH₃ and H, and R⁴ is selected from the group consisting of

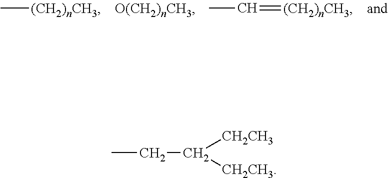

The CDO precursor and carrier gas are ionized in presence of RF power. RF power is applied a power level and a first frequency to the CDO precursor to activate the CDO precursor so that a CDO layer is deposited on the substrate 201. During operation 303, the pressure in the process chamber 114a is about 4 torr to about 35 torr and the temperature in the process chamber 114a and temperature of the substrate 201 is between about 350 Celsius (° C.) and 400° C. The temperature between about 350° C. and 400° C. in the process chamber 114a increases the modulus and hardness of the CDO layer. The crosslinked Si—O—Si and Si—CH₂—Si bonds of the CDO precursor do not degrade at temperatures between about 350° C. and 400° C., and thus remain cross-linked in the deposited film, thereby increasing the modulus and hardness of the CDO layer. In one embodiment, which can be combined with other embodiments described herein, the CDO layer has a modulus is greater than 25 GPa, a hardness greater than 4.5 GPa, and a dielectric constant less than 4.

The CDO precursor of Compounds 1-6 and Formula 1, and combinations thereof, is selected such that the hardness of the CDO layer is greater than 4.5 GPa and the dielectric constant of the CDO layer is less than 4. Not to be bound by theory, Si—O—Si bonds are incorporated into CDO layer via condensation of —OR groups (such as —OCH₂CH₃ and —OCH₃) of the CDO precursor during operation 303 or via built in Si—O—Si bonds of the CDO precursor of Compounds 1-6 and Formula 1, and combinations thereof. Si—O bonds have a greater bond strength that Si—C bonds, and thus the incorporation of Si—O—Si bonds into CDO layer provide for a higher mechanical strength resulting in the hardness greater than 4.5 GPa. Furthermore, terminal Si—CH₃ groups of the CDO precursor incorporate more terminal carbon and incorporate more non-polar Si—C bonds in the CDO layer in addition to the formation of microporosities in the CDO layer. The dielectric constant of the CDO layer is decreased via the incorporation of terminal carbon and non-polar Si—C bonds in the CDO layer and microporosities in the CDO layer formed from the terminal Si—CH₃ groups. Additionally, built in Si—CH₂—Si bonds in the CDO precursor incorporate more networked carbon to control the percentage of carbon (contributing to the dielectric constant) and the mechanical strength of the CDO layer. Thus, Compounds 1-6 and Formula 1, and combinations thereof, are selected for the CDO precursor to control the ratio of Si—O bonds to Si—C bonds in the deposited CDO layer such that the hardness of the CDO layer is greater than 4.5 GPa and the dielectric constant of the CDO layer less than 4.

When the at least one of the oxygen-containing gas and the hydrogen-containing gas are provided to the processing volume 204, at least one of oxygen and hydrogen ions/radicals are generated in response to the application of RF power. The oxygen and hydrogen ions/radicals react with loosely bound CHx and SiCH₂Si groups and terminating SiCH₃ groups. However, the loosely bound CHx is aggressively removed and the byproducts of the reaction with the loosely bound CHx and SiCH₂Si groups and terminating SiCH₃ groups are exhausted from the processing chamber. Removal of the loosely bound CHx and SiCH₂Si introduces microporosities into the CDO layer due to removal of CHx type carbon and some terminating SiCH₃ type carbon. The microporosities decrease the dielectric constant of the CDO layer without increasing the modulus and hardness of the CDO layer.

During processing, the power level of the RF power is about 200 Watts (W) to about 2000 W. The first frequency of the RF power is about 13.56 megahertz (MHz) to about 40 MHz. In one example, the first frequency plasma facilitates preservation of the linear backbone of the Si—O—Si structure and terminal Si—CH₃ groups to maintain the hardness and dielectric constant of the CDO layer. With a first frequency not less than 27 MHz there is less ion energy and bombardment so the backbone of the CDO precursor is protected from being fragmented in the gas phase such that the ratio of Si—O bonds to Si—C bonds is maintained. Once SiOC long chain polymers of the precursor are deposited on the substrate, the RF power may be applied at a second frequency not greater than 350 kilohertz (kHz) to remove excess carbon from the CDO layer to increase the dielectric constant by inducing fragmentation of terminal Si—CH₃ groups such that the dielectric constant of the CDO layer is between about 3 and about 4.

In summation, a method forming a low-k CDO layer by a PECVD process is described herein. The resulting CDO layer has a dielectric constant less than 4 and hardness greater than 4.5 GPa. In one embodiment the dielectric constant is between about 3.10 and about 3.20, and the hardness is between about 4.8 and 5.4 GPa. Therefore, the resulting low-k CDO layer has a high mechanical strength to withstand high shear stresses during a subsequent CMP process which would otherwise lead to cracks and device failure. The compounds utilized for the CDO precursor have crosslinked Si—O—Si bonds to increase the modulus and hardness of the low-k CDO layer and withstand a temperature in the chamber greater than 350° C. A temperature in the chamber greater than 350° C. in the chamber during the PECVD increases the modulus and hardness of the CDO layer. Therefore, the CDO layers have a dielectric constant less than 4 and hardness greater than 4.5 GPa. The dielectric constant less than 4 and hardness greater than 4.5 GPa eliminates the need to preform carbon doping and UV curing. Carbon doping decreases the dielectric constant and hardness of CDO layers, and UV curing increases the dielectric constant and hardness of CDO layers. Eliminating carbon doping and UV curing increases yield, decreases costs, and decreases customer cost of ownership.

While the foregoing is directed to examples of the present disclosure, other and further examples of the disclosure may be devised without departing from the basic scope thereof, and the scope thereof is determined by the claims that follow.

1. A method of forming a carbon-doped silicon oxide (CDO) layer, comprising:
providing a carrier gas at a carrier gas flow rate and a CDO precursor at a precursor flow rate to a process chamber, the CDO precursor is selected from the group consisting of: 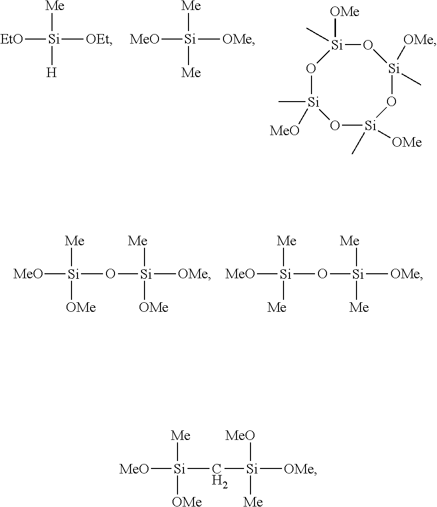
and mixtures thereof;
applying a radio frequency (RF) power at a power level and a frequency to the CDO precursor; and
depositing a CDO layer on a substrate within the process chamber.

2. The method of claim 1, further comprising providing at least one of an oxygen-containing gas at an oxygen-containing gas flow rate and a hydrogen-containing gas at a hydrogen-containing gas flow rate to the process chamber.

3. The method of claim 2, wherein the oxygen-containing gas flow rate is about 0 standard cubic centimeters per minute (sccm) to about 100 sccm.

4. The method of claim 3, wherein the oxygen-containing gas is oxygen gas (O₂).

5. The method of claim 2, wherein the hydrogen-containing gas flow rate is about 0 sccm to about 2000 sccm.

6. The method of claim 5, wherein the hydrogen-containing gas is hydrogen gas (H₂).

7. The method of claim 1, further comprising:
transferring the substrate to a substrate support of to the process chamber; and
raising the substrate support an elevated processing position to a process position.

8. The method of claim 7, wherein the process position is a process distance from about 0.3 inches (inch) to about 1.2 inch from a showerhead of the process chamber.

9. The method of claim 1, wherein the carrier gas flow rate is about 300 standard cubic centimeters per minute (sccm) to about 5000 sccm.

10. The method of claim 9, wherein the carrier gas is helium (He).

11. The method of claim 1, wherein the precursor flow rate is about 150 milligrams per minute (mgm) to about 1500 mgm.

12. The method of claim 1, wherein the power level is about 200 Watts (W) to about 2000 W.

13. The method of claim 1, wherein the frequency is about 13.56 megahertz (MHz) to about 40 MHz.

14. A method of forming a carbon-doped silicon oxide (CDO) layer, comprising:
providing a carrier gas at a carrier gas flow rate and a CDO precursor at a precursor flow rate to a process chamber, the CDO precursor represented by Formula 1: 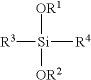
wherein, in Formula 1, R¹ and R₂ are independently selected from the group consisting of a C₁-C₂₀ alkyl group, R³ is selected from the group consisting of a C₁-C₂₀ alkyl group and hydrogen (H), and R⁴ is selected from the group consisting of a C₁-C₂₀ alkyl group and a C₁-C₂₀ alkoxy group;
applying a radio frequency (RF) power at a power level and a frequency to the CDO precursor; and
depositing a CDO layer on a substrate within the process chamber.

15. The method of claim 14, further comprising:
transferring the substrate to a substrate support of to the process chamber; and
raising the substrate support an elevated processing position to a process position.

16. The method of claim 15, wherein the process position is a process distance from about 0.3 inches (inch) to about 1.2 inch from a showerhead of the process chamber.

17. The method of claim 14, wherein the precursor flow rate is about 150 milligrams per minute (mgm) to about 1500 mgm.

18. The method of claim 14, wherein the power level is about 200 Watts (W) to about 2000 W.

19. The method of claim 14, wherein the frequency is about 13.56 megahertz (MHz) to about 40 MHz.

20. A method of forming a carbon-doped silicon oxide (CDO) layer, comprising:
providing a carrier gas at a carrier gas flow rate and a CDO precursor at a precursor flow rate to a process chamber, the CDO precursor represented by Formula 1: 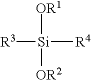
wherein, in Formula 1, R¹ is selected from the group consisting of —CH₃ and —CH₂CH₃, R² is selected from the group consisting of —CH₃ and —CH₂CH₃, R³ is selected from the group consisting of —CH₃ and H, and R⁴ is selected from the group consisting of 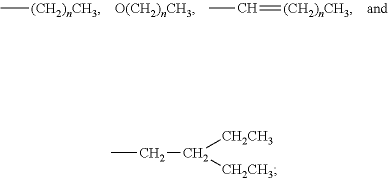
applying a radio frequency (RF) power at a power level and a frequency to the CDO precursor; and
depositing a CDO layer on a substrate within the process chamber.
